(19) United States
(12) Patent Application Publication
(10) Pub. No.: US 2007/0184630 A1
(43) Pub. Date: Aug. 9, 2007

(54) Method of bonding a semiconductor wafer to a support substrate

(76) Inventors: John Melvyn Cullen, Darlington (GB); Suzanne Combe, Darlington (GB)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/349,566

(22) Filed: Feb. 8, 2006

(30) Foreign Application Priority Data
Feb. 7, 2006 (GB) 0602410.3

(51) Int. Cl. H01L 21/46; H01L 23/12

(52) U.S. Cl. 438/455; 438/458; 257/632; 257/701

(57) ABSTRACT

A method of bonding a semiconductor wafer to a support substrate comprising the steps of: providing a semiconductor wafer; coating at least part of one face of the wafer with a water soluble coating layer; providing a double sided adhesive tape, at least one side of the adhesive tape comprising a thermal release adhesive; adhering the double sided adhesive tape to coating layer by means of said thermal release adhesive; adhering the reverse side of the adhesive tape to the support substrate.

The present invention relates to a method of bonding a seminconductor wafer to a support substrate, a bonded structure resulting from such a method and a method of debonding such a structure.

Temporary bonding of semiconductor wafers to support substrates is a critical stage in the manufacturing of semiconductor, in particular GaAs, based devices. It enables wafers to be thinned whilst maintaining enough rigidity for further back face processing. The bonding material must be able to withstand the variety of back face processes that are required when addressing several product families. Key performance indicators such as cycle time, final wafer thickness, total thickness variation, mechanical and visual yield are also of significant importance.

Wax bonding is known. According to this method a photo resist protective coat is applied to the active face of the wafer and a dry wax film then used to temporarily bond the wafer to the support sapphire. This method provides excellent thickness control and within wafer variation. However, a lengthy and expensive solvent de-bonding process is required. The de-bonding process also necessitates the handling of unsupported thin wafers.

The method according to the invention seeks to overcome these problems.

Accordingly, in a first aspect, the present invention provides a method of bonding a semiconductor wafer to a support substrate comprising the steps of:
providing a semiconductor wafer;
coating at least part of one face of the wafer with a water soluble coating layer;
providing a double sided adhesive tape, at least one side of the adhesive tape comprising a thermal release adhesive;
adhering the double sided adhesive tape to coating layer by means of said thermal release adhesive;
adhering the reverse side of the adhesive tape to the support substrate. Such a method allows for rapid bonding and de-bonding.

Preferably the semiconductor wafer is a GaAs wafer.

Both sides of the tape can be coated with a thermal release adhesive.

Alternatively one side of the tape is coated with a thermal release adhesive and the opposite side is coated with a non-thermal release adhesive.

The adhesive tape can be Revalpha.

The coating layer can be water soluble PVA solution, preferably Emulsitone.

The support substrate can be sapphire.

In a further aspect of the invention there is provided a method of de-bonding a semiconductor wafer and support structure as bonded by the method of claim 1, comprising the steps of:
heating the wafer to separate the wafer coating layer from the adhesive tape;
rinsing the wafer to remove the water soluble coating layer.

Preferably, the wafer is mounted to a film frame during rinsing.

In a further aspect of the invention there is provided a bonded structure comprising:
a semiconductor wafer;
a wafer soluble coating layer on one side of the wafer;
a double sided adhesive tape, at least one side of which comprises a thermal release adhesive, the adhesive tape being adhered to the coating layer by means of the thermal release adhesive; and
a substrate adhered to the opposite side of the adhesive layer.

The wafer can be GaAs.

The coating layer can be PVA, preferably Emulsitone.

The adhesive tape can be Revalpha.

The present invention will now be described by way of example only and not in any limitative sense with reference to the accompanying drawings in which

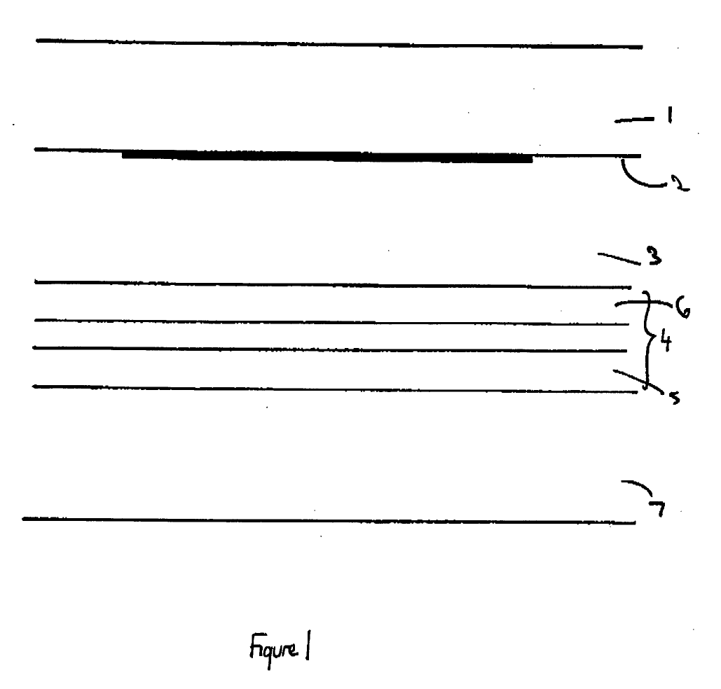

FIG. 1 shows a bonded structure according to the invention.

In a method according to the invention a GaAs semiconductor wafer 1 is provided. The active face 2 of the wafer 1 is coated with a water soluble coating layer 3 (in this embodiment Emulsitone, a water soluble PVA solution). This layer protects the active face 2 of the wafer 1.

A double sided adhesive tape 4 is adhered to the coating layer 3. The adhesive tape 4 comprises an ordinary adhesive S on one side and a thermal release adhesive 6 on the other. The tape 4 is applied with the thermal release adhesive 6 towards the wafer surface 2. The reverse side of the adhesive tape 4 is then adhered to the sapphire support substrate 7. The final bonded wafer and substrate is shown in FIG. 1. In this embodiment the adhesive tape is Revalpha (Trade Mark) as disclosed in U.S. Pat. No. 6,777,310, U.S. Pat. No. 6,803,293 and U.S. Pat. No. 6,930,023, the contents of which are herein incorporated by reference.

Secure adhesion between wafer 1 and support substrate 7 can be achieved at room temperature capable of withstanding the mechanical grind process and wet chemical stress relief process.

Once a wafer 1 has received the back face processing it can be de-bonded rapidly from the sapphire support 7 by applying heat. Heating the adhesive tape 4 above the release temperature initiates a foaming reaction in the thermal release adhesive 6 side, within seconds adhesive strength reduces to near zero as a result of decreased contact area The wafer 1 and the support substrate 7 can then be separated easily.

The ability to maintain a uniform and repeatable bond thickness is deemed process critical when thinning wafers 1 in a volume environment. Wafers 1 are processed in batches of up to 18, therefore any within wafer thickness variation or wafer-to-wafer inconsistency of the bond will result in poor control of final wafer thickness. Bonding wafers 1 with adhesive tape 4 successfully enables temporary wafer bonding with exceptional final wafer thickness process capability. Process performance regularly demonstrates Cpk greater than 1.7.

Of equal importance is wafer cycle time. Utilising adhesive tape 4 enables throughput of the wafer-thinning module to increase significantly without the necessity to invest in expensive de-bonding equipment. The process cycle time for a wax-bonded wafer in contrast is lengthy due to the time consuming solvent demount stages. These processes utilise expensive solvents, which are used at an elevated temperature. The chemical exchange frequency required to ensure wafer cleanliness makes the wax bonding process unsuitable to sustain 24 hr continuous operation. During this high temperature solvent process the thinned wafer is predominantly unsupported posing mechanical yield concerns. Whereas utilising adhesive tape 4 allows for the wafer 1 to be mounted to film frame immediately after the sapphire substrate 7 is removed. The supported wafer 1 will progress for cleaning on wafer test and die singulation. Given that the thinned wafer is almost always supported the resulting mechanical yield consistently exceeds 99%.

The water soluble protective coat 3 remains in place until the entire process is complete. Once mounted to film frame the final process step is to wash the wafer 1 removing the protective film 3 along with any particulates. This technique ensures no damage to active device structures as well as exceptional visual quality. After cleaning the wafer 1 is spun dry and progressed to end of fab final automated inspection.

In an alternative embodiment of the invention (not shown) the adhesive tape 4 comprises a protective liner on one or more face. This is removed before use.

In a further alternative embodiment (not shown) the adhesive tape 4 comprises a thermal release adhesive 6 on both sides.

1. A method of bonding a semiconductor wafer to a support substrate comprising the steps of:
providing a semiconductor wafer;
coating at least part of one face of the wafer with a water soluble coating layer;
providing a double sided adhesive tape, at least one side of the adhesive tape comprising a thermal release adhesive;
adhering the double sided adhesive tape to coating layer by means of said thermal release adhesive;
adhering the reverse side of the adhesive tape to the support substrate.

2. A method as claimed in claim 1, wherein the semiconductor wafer is a GaAs wafer.

3. A method as claimed in claim 1, wherein both sides of the tape are coated with a thermal release adhesive.

4. A method as claimed in claim 1, wherein one side of the tape is coated with a thermal release adhesive and the opposite side is coated with a non-thermal release adhesive.

5. A method as claimed in claim 4, wherein the adhesive tape is Revalpha.

6. A method as claimed in claim 1, wherein the coating layer is a water soluble PVA solution, preferably Emulsitone.

7. A method as claimed in claim 1, wherein the support substrate is sapphire.

8. A method of de-bonding a semiconductor wafer and support structure as bonded by the method of claim 1, comprising the steps of:
heating the wafer to separate the wafer coating layer from the adhesive tape;
rinsing the wafer to remove the water soluble coating layer.

9. A method as claimed in claim 8, wherein the wafer is mounted to a film frame after release from the substrate.

10. A bonded structure comprising:
a semiconductor wafer;
a wafer soluble coating layer on one side of the wafer;
a double sided adhesive tape, at least one side of which comprises a thermal release adhesive, the adhesive tape being adhered to the coating layer by means of the thermal release adhesive; and
a substrate adhered to the opposite side of the adhesive layer.

11. A bonded structure as claimed in claim 10, wherein the wafer is GaAs.

12. A bonded structure as claimed in claim 10, wherein the coating layer is PVA, preferably Emulsitone.

13. A bonded structure as claimed in claim 10, wherein the adhesive tape is Revalpha.
